(19) United States
(12) Patent Application Publication
(10) Pub. No.: US 2026/0141926 A1
(43) Pub. Date: May 21, 2026

(54) MEMORY DEVICE INCLUDING BLOCK SELECTION CIRCUIT

(71) Applicant: SK hynix Inc., Icheon-si (KR)

(72) Inventors: Sang Hyun SUNG, Icheon-si (KR); Jin Ho KIM, Icheon-si (KR)

(21) Appl. No.: 19/086,923

(22) Filed: Mar. 21, 2025

(30) Foreign Application Priority Data
Nov. 18, 2024 (KR) 10-2024-0164029

(51) Int. Cl. G11C 5/02; G11C 5/06; G11C 16/08; H10B 41/20; H10B 41/35; H10B 41/41; H10B 43/20; H10B 43/35; H10B 43/40

(52) U.S. Cl. CPC G11C 5/025; G11C 5/063; G11C 16/08; H10B 41/20; H10B 41/35; H10B 41/41; H10B 43/20; H10B 43/35; H10B 43/40

(57) ABSTRACT

A memory device including a first semiconductor layer including a slim area, and a first cell area and a second cell area respectively arranged on both sides of the slim area in a first horizontal direction, and a second semiconductor layer, which vertically overlaps with the first semiconductor layer, and includes a pass transistor circuit connected to the first cell area and the second cell area through a word line, a block selection circuit for providing a block selection signal to the pass transistor circuit, and a voltage switch circuit for transmitting an operating voltage to the pass transistor circuit, wherein the voltage switch circuit may include a voltage switch region disposed in an under-slim region of the second semiconductor layer, wherein the under-slim region vertically overlaps with the slim area, and at least a part of the block selection circuit may be disposed in the under-slim region.

### CROSS-REFERENCE TO RELATED APPLICATION

The present application claims priority under 35 U.S.C. § 119(a) to Korean patent application number 10-2024-0164029 filed in the Korean Intellectual Property Office on Nov. 18, 2024, which is incorporated herein by reference in its entirety.

### TECHNICAL FIELD

Embodiments of the present disclosure relate to a memory device including a block selection circuit.

### BACKGROUND

A three-dimensional memory device with memory cells arranged three-dimensionally have been proposed for use. Three-dimensional memory devices have the advantage of implementing a greater capacity in the same area by vertically stacking memory cells, thereby providing high performance and superior power efficiency. A memory device may include a plurality of memory blocks and a block selection circuit for selecting one of the plurality of memory blocks.

### SUMMARY

Embodiments of the disclosure may provide a memory device capable of being reduced in size.

The objects of embodiments of the present disclosure are not limited to the objects described in this specification, and other objects not mentioned will be clearly understood by those skilled in the art from the description below.

Embodiments of the disclosure may provide a memory device including a first semiconductor layer including a slim area, and a first cell area and a second cell area respectively arranged on both sides of the slim area in a first horizontal direction, and a second semiconductor layer, which vertically overlaps with the first semiconductor layer, and includes a pass transistor circuit connected to the first cell area and the second cell area through a word line, a block selection circuit for providing a block selection signal to the pass transistor circuit, and a voltage switch circuit for transmitting an operating voltage to the pass transistor circuit, wherein the voltage switch circuit includes a voltage switch region disposed in an under-slim region of the second semiconductor layer, wherein the under-slim region vertically overlaps with the slim area, and wherein at least a part of the block selection circuit is disposed in the under-slim region.

Embodiments of the disclosure may provide a memory device including a first semiconductor layer including a cell area and a slim area that are arranged in a first horizontal direction, and a second semiconductor layer that vertically overlaps with the first semiconductor layer and includes a pass transistor circuit connected to the cell area through a word line, a block selection circuit providing a block selection signal to the pass transistor circuit, and a voltage switch circuit transmitting an operating voltage to the pass transistor circuit, wherein the voltage switch circuit includes a voltage switch region disposed in an under-slim region of the second semiconductor layer, wherein the under-slim region vertically overlaps with the slim area, and wherein at least a part of the block selection circuit is disposed in the under-slim region.

According to embodiments of the present disclosure, it is possible to provide a memory device capable of increasing layout utilization efficiency and reducing size.

The effects of embodiments of the present disclosure are not limited to the effects mentioned above, and other effects not mentioned will be clearly understood by those skilled in the art from the description of the claims.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 is a schematic block diagram of a memory device according to embodiments of the present disclosure.

FIG. 2 is a block diagram illustrating a row decoder of FIG. 1.

FIG. 3 is a perspective view of a memory device according to embodiments of the present disclosure.

FIG. 4 and FIG. 5 are plan views schematically illustrating a first under-cell region, a second under-cell region and under-slim regions of a first semiconductor layer according to embodiments of the present disclosure.

### DETAILED DESCRIPTION

Hereinafter, various embodiments of the present disclosure will be described in detail with reference to accompanying drawings. In the following description of examples or embodiments of the present disclosure, reference will be made to the accompanying drawings in which it is shown by way of illustration specific examples or embodiments that can be implemented, and in which the same reference numerals and signs can be used to designate the same or like components, even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention more unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc., are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, it will be described various embodiments of the disclosure in detail with reference to the accompanying drawings.

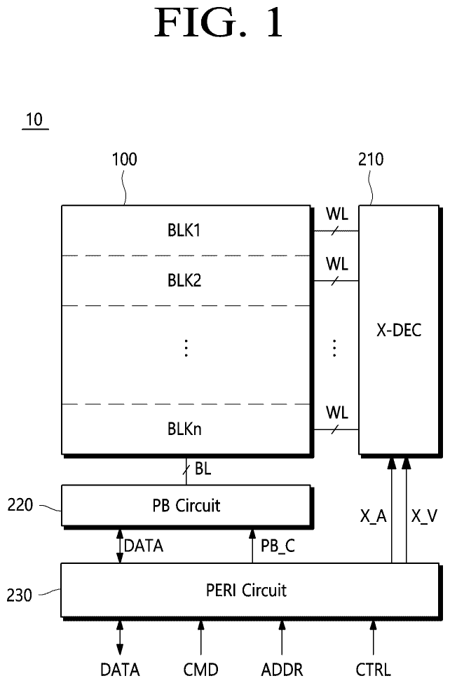

FIG. 1 is a schematic block diagram of a memory device according to an embodiment of the present disclosure.

Referring to FIG. 1, a memory device 10 according to an embodiment of the present disclosure includes a memory cell array 100, a row decoder (e.g., X-DEC) 210, a page buffer circuit (e.g., PB Circuit) 220, and a peripheral circuit (e.g., PERI Circuit) 230. The memory cell array 100 may include a plurality of memory blocks BLK1-BLKn. Each of the memory blocks BLK1-BLKn may include a plurality of memory cells. The memory cells may be, for example, flash memory cells. Hereinafter, memory cells are described as NAND flash memory cells, but the present disclosure is not limited thereto. The memory cells may also be resistive memory cells such as ReRAM, PRAM, or MRAM.

The memory blocks BLK1-BLKn may be connected to the row decoder 210 through word lines WL. The memory blocks BLK1-BLKn may be connected to the page buffer circuit 220 through a plurality of bit lines BL.

The row decoder 210 may select one of a plurality of memory blocks BLK1-BLKn included in the memory cell array 100 in response to a row address X_A provided from a peripheral circuit 230. The row decoder 210 may transfer an operating voltage X_V provided from the peripheral circuit 230 to word lines WL of the selected memory block.

The page buffer circuit 220 may receive a page buffer control signal PB_C from the peripheral circuit 230, and may transmit and receive a data signal DATA to and from the peripheral circuit 230. The page buffer circuit 220 may control bit lines BL arranged in the memory cell array 100 in response to the page buffer control signal PB_C. For example, the page buffer circuit 220 may detect data stored in a memory cell of the memory cell array 100 by detecting a signal of a bit line BL of the memory cell array 100 in response to the page buffer control signal PB_C, and may transmit a data signal DATA to the peripheral circuit 230 according to the detected data. The page buffer circuit 220 may apply a signal to the bit line BL according to a data signal DATA received from the peripheral circuit 230 in response to the page buffer control signal PB_C, and may write data to the memory cell of the memory cell array 100 accordingly. The page buffer circuit 220 may write data to the memory cell connected to the word line activated by the row decoder 210 or read data therefrom.

The peripheral circuit 230 may receive a command signal CMD, an address signal ADDR, and a control signal CTRL from the outside of the memory device 10, and may transmit and receive data DATA with a device outside of the memory device 10, such as a memory controller. The peripheral circuit 230 may output signals for writing data to the memory cell array 100 or reading data from the memory cell array 100, such as a row address X_A and a page buffer control signal PB_C, according to a command signal CMD, an address signal ADDR, and a control signal CTRL. The peripheral circuit 230 may generate various voltages required by the memory device 10, including an operating voltage X_V.

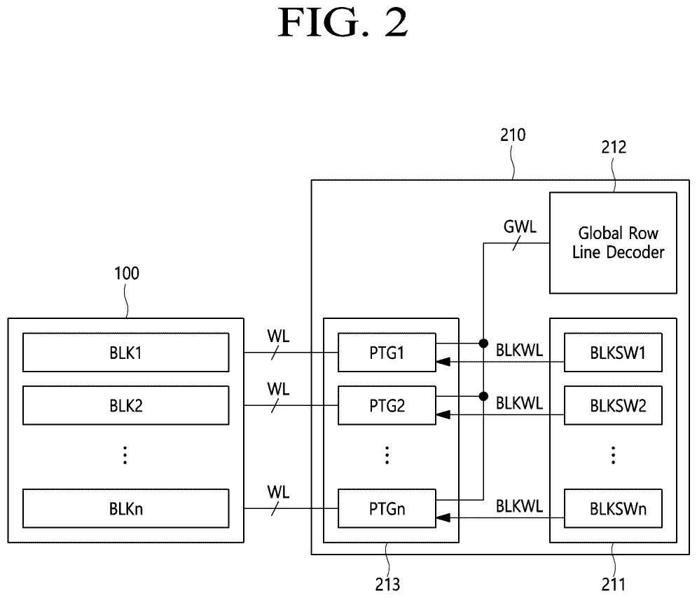

FIG. 2 is a block diagram illustrating a row decoder of FIG. 1.

Referring to FIG. 2, a row decoder 210 may include a block selection circuit 211, a global row line decoder 212, and a pass transistor circuit 213.

The block selection circuit 211 may include a plurality of block switches BLKSW1-BLKSWn corresponding to a plurality of memory blocks BLK1-BLKn, respectively. The block switches BLKSW1-BLKSWn may be connected to the pass transistor circuit 213 through block selection signal lines BLKWL. One of the plurality of block switches BLKSW1-BLKSWn may be selected in response to a row address received from a peripheral circuit. The selected block switch may output an activated block selection signal to a corresponding block selection signal line BLKWL.

The global row line decoder 212 may be connected to the pass transistor circuit 213 via the global word lines GWL. The global row line decoder 212 may receive operating voltages from a peripheral circuit and output the operating voltages to the global word lines GWL in response to a control signal received from the peripheral circuit. The global row line decoder 212 may include a plurality of switching elements that transmit the operating voltages to the global word lines GWL.

The pass transistor circuit 213 may include a plurality of pass transistor groups PTG1-PTGn corresponding to a plurality of memory blocks BLK1-BLKn. Each pass transistor group may include a plurality of pass transistors connected to the word lines WL of the corresponding memory block.

The pass transistor groups PTG1-PTGn may be connected to the block switches BLKSW1-BLKSWn respectively through the block signal lines BLKWL. The gate electrodes of the pass transistors included in each pass transistor group may be commonly connected to one block signal line. If the block selection signal provided to the pass transistor group through the block signal line is activated, the pass transistors included in the pass transistor group may be turned on.

Each of the pass transistor groups PTG1-PTGn may be connected to the global row line decoder 212 via the global word lines GWL. The global word lines GWL may be commonly connected to the plurality of pass transistor groups PTG1-PTGn. That is, the plurality of pass transistor groups PTG1-PTGn may share the global word lines GWL.

One pass transistor group selected from among the pass transistor groups PTG1-PTGn, i.e., a pass transistor group receiving a block selection signal activated from a block selection circuit 211, may transmit operating voltages provided from a global row line decoder 212 to a corresponding memory block through word lines WL.

Hereinafter, in the attached drawings, two directions parallel to an upper surface of a first semiconductor layer or a second semiconductor layer will be defined as a first horizontal direction HD1 and a second horizontal direction HD2, respectively, and a direction protruding vertically from the upper surface of the first semiconductor layer and the second semiconductor layer will be defined as the vertical direction VD. For example, the first horizontal direction HD1 may be the extension direction of word lines or an arrangement direction of bit lines, and the second horizontal direction HD2 may be the extension direction of bit lines or an arrangement direction of word lines. The first horizontal direction HD1 and the second horizontal direction HD2 may intersect each other perpendicularly.

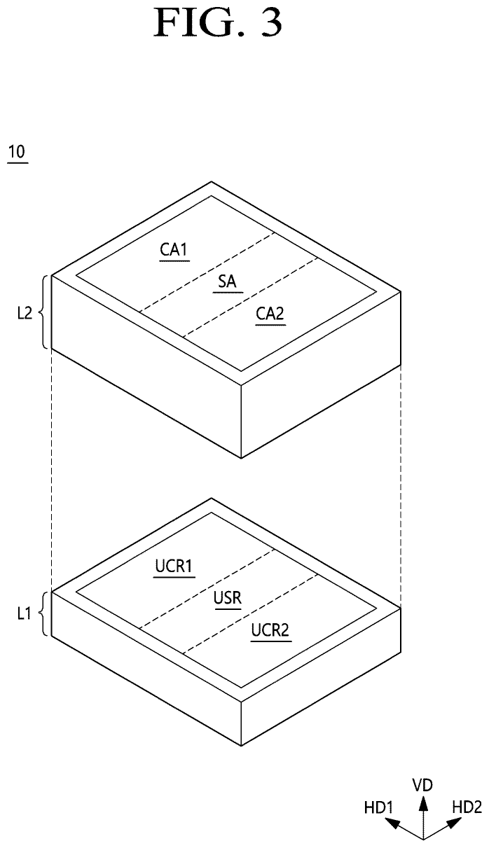

FIG. 3 is a perspective view of a memory device according to embodiments of the present disclosure.

Referring to FIG. 3, a memory device 10 may include a first semiconductor layer L1 and a second semiconductor layer L2. The first semiconductor layer L1 and the second semiconductor layer L2 may overlap with each other in the vertical direction VD. For example, the first semiconductor layer L1 may be disposed below the second semiconductor layer L2 in the vertical direction VD.

In FIG. 3, the first semiconductor layer L1 and the second semiconductor layer L2 may be spaced apart from each other in the vertical direction VD, but this exploded view is for explanatory purposes, and it should be understood that an upper surface of the first semiconductor layer L1 and a lower surface of the second semiconductor layer L2 may be in contact with each other.

In an embodiment, a row decoder (210 of FIG. 1), a page buffer circuit (220 of FIG. 1), and a peripheral circuit (230 of FIG. 1) may be disposed on the first semiconductor layer L1, and a memory cell array (110 of FIG. 1) may be disposed on the second semiconductor layer L2.

In the second semiconductor layer L2, a plurality of word lines may extend in a first horizontal direction HD1, and a plurality of bit lines may extend in a second horizontal direction HD2. In an embodiment, the second semiconductor layer L2 may include a first cell area CA1, a second cell area CA2, and a slim area SA. The first cell area CA1 and the second cell area CA2 may be disposed on both sides of the slim area SA in the first horizontal direction HD1, respectively.

Although not shown, a plurality of word lines may be stacked in a vertical direction VD in the first cell area CA1 and the second cell area CA2, and the slim area SA, to form a stack structure. A plurality of semiconductor pillars may penetrate the stack structure in a vertical direction VD in the first cell area CA1 and the second cell area CA2. The word lines may be combined with the semiconductor pillars penetrating the stack structure in the vertical direction VD to form three-dimensionally arranged memory cells. The second semiconductor layer L2 may include a first cell array arranged in the first cell area CA1 and a second cell array arranged in the second cell area CA2.

The first semiconductor layer L1 may include a substrate, and a row decoder, a page buffer circuit, and a peripheral circuit, which may be configured in the first semiconductor layer L1 by forming semiconductor elements such as transistors and wiring connected to the semiconductor elements on the substrate.

The first semiconductor layer L1 may include a first under-cell region UCR1 that overlaps with the first cell area CA1 in a vertical direction VD, a second under-cell region UCR2 that overlaps with the second cell area CA2 in a vertical direction VD, and an under-slim region USR that overlaps with the slim area SA in a vertical direction VD. The first under-cell region UCR1 and the second under-cell region UCR2 may be respectively arranged on both sides of the under-slim region USR in the first horizontal direction HD1.

The memory device 10 may have a Peri-Over-Cell (POC) structure. That is, the first semiconductor layer L1 and the second semiconductor layer L2 may be manufactured on different wafers and then bonded to each other using a wafer bonding technique.

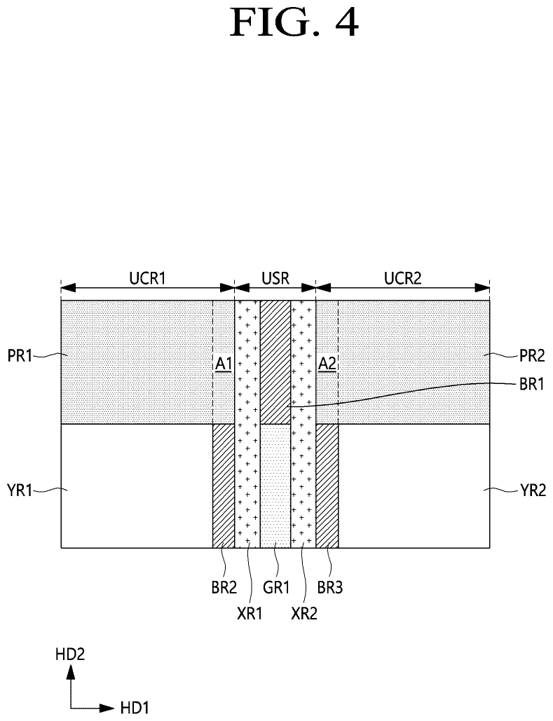

FIG. 4 is a plan view schematically illustrating a first under-cell region, a second under-cell region, and under-slim regions of a first semiconductor layer according to embodiments of the present disclosure.

Referring to FIG. 4, an under-slim region USR may include a first pass transistor region XR1, a second pass transistor region XR2, a voltage switch region GR1, and a first block switch region BR1.

The first under-cell region UCR1 may include a first peripheral circuit region PR1, a first page buffer region YR1, and a second block switch region BR2. The second under-cell region UCR2 may include a second peripheral circuit region PR2, a second page buffer region YR2, and a third block switch region BR3.

The first pass transistor region XR1 and the second pass transistor region XR2 may be regions where pass transistor circuits are located, and the pass transistor circuits may be divided into two sections and disposed in the first pass transistor region XR1 and the second pass transistor region XR2. The first pass transistor region XR1 and the second pass transistor region XR2 may be connected to the first cell area CA1 and the second cell area CA2 of FIG. 3 respectively through a plurality of word lines (not shown).

The first page buffer regions YR1 and the second page buffer region YR2 may be regions where the page buffer circuit is located, and the page buffer circuit can be divided into two sections and disposed in the first page buffer regions YR1 and the second page buffer region YR2. The first page buffer regions YR1 and the second page buffer region YR2 may be connected to the first cell area CA1 and the second cell area CA2 of FIG. 3 respectively through a plurality of bit lines (not shown).

The voltage switch region GR1 may be a region where at least a part of the voltage switch circuit included in the global row line decoder is disposed, and at least a portion of the voltage switch circuit may be connected to the first pass transistor region XR1 and the second pass transistor region XR2 through global word lines.

The first block switch region BR1, the second block switch region BR2 and the third block switch region BR3 may be regions where the block selection circuit is disposed, and the block selection circuit may be connected to the first pass transistor region XR1 and the second pass transistor region XR2 through block signal lines.

In the under-slim region USR, the first pass transistor region XR1 and the second pass transistor region XR2 may be disposed to be spaced apart from each other in the first horizontal direction HD1, and the voltage switch region GR1 may be disposed between the first pass transistor region XR1 and the second pass transistor region XR2.

The dimension of the voltage switch region GR1 in the second horizontal direction HD2 is smaller than the dimension of the under-slim region USR in the second horizontal direction HD2. Due to the size difference between the dimension of the under-slim region USR in the second horizontal direction HD2 and the dimension of the voltage switch region GR1 in the second horizontal direction HD2, an open area or an empty area may be created in the under-slim region USR. According to an embodiment of the present disclosure, a first block switch region BR1 may be disposed to fill the open area of the under-slim region USR.

The first block switch region BR1 may be arranged between the first pass transistor region XR1 and the second pass transistor region XR2, and may overlap with the voltage switch region GR1 in the second horizontal direction HD2.

The second block switch region BR2 and the third block switch region BR3 may be disposed to overlap with the first page buffer region YR1 and the second page buffer region YR2 in the first horizontal direction HD1. The second block switch region BR2 may be disposed between the under-slim region USR and the first page buffer region YR1, and the third block switch region BR3 may be disposed between the under-slim region USR and the second page buffer region YR2.

The first peripheral circuit region PR1 may be the remaining region of the first under-cell region UCR1 excluding the second block switch region BR2 and the first page buffer region YR1. The first peripheral circuit region PR1 may include a first region A1 that overlaps with the second block switch region BR2 in the second horizontal direction HD2.

The second peripheral circuit region PR2 may be the remaining region of the second under-cell region UCR2 excluding the third block switch region BR3 and the second page buffer region YR2. The second peripheral circuit region PR2 may include a second region A2 that overlaps with the third block switch region BR3 in the second horizontal direction HD2. The first peripheral circuit region PR1 and the second peripheral circuit region PR2 may overlap with the first block switch region BR1 in the first horizontal direction HD1.

Because the first block switch region BR1 is disposed in the under-slim region USR, rather than in the first under-cell region UCR1 or the second under-cell region UCR2, the area available for arranging peripheral circuits in the first under-cell region UCR1 and the second under-cell region UCR2 can be increased. In the under-cell regions, and the ratio of the peripheral circuit regions and the page buffer regions to the block switch regions also increases, thereby allowing potential reduction the size of the memory device.

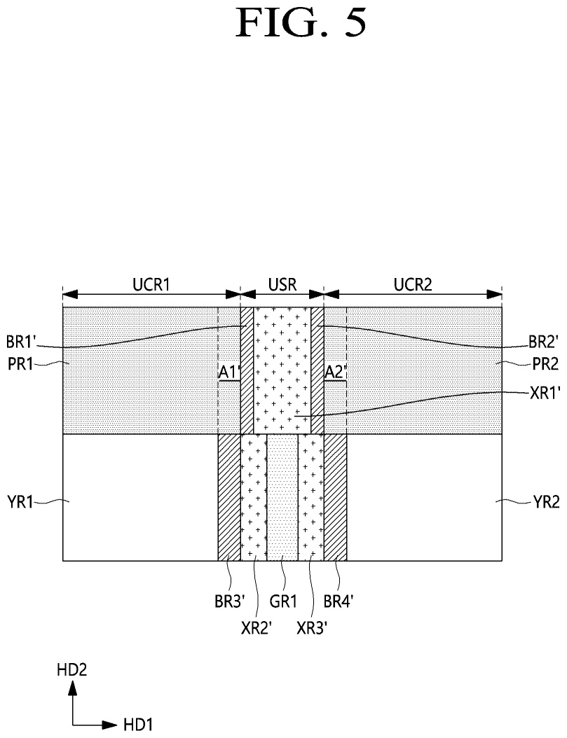

FIG. 5 is a plan view schematically illustrating a first under-cell region, a second under-cell region, and an under-slim region of a first semiconductor layer according to an embodiment of the present disclosure.

Referring to FIG. 5, the under-slim region USR may include a first pass transistor region XR1′, a second pass transistor region XR2′, a third pass transistor region XR3′, a first block switch region BR1′, a second block switch region BR2′, and the voltage switch region GR1.

The first under-cell region UCR1 may include a first peripheral circuit region PR1, a first page buffer region YR1, and a third block switch region BR3′. The second under-cell region UCR2 may include a second peripheral circuit region PR2, a second page buffer region YR2, and a fourth block switch region BR4′.

The first pass transistor region XR1′, the second pass transistor region XR2′, and the third pass transistor region XR3′ may be regions where pass transistor circuits are disposed, and the pass transistor circuits may be divided into three sections or groups and disposed in the first pass transistor region XR1′, the second pass transistor region XR2′, and the third pass transistor region XR3′.

The voltage switch region GR1 may overlap with the first pass transistor region XR1′ in the second horizontal direction HD2 .The second pass transistor region XR2′ and the third pass transistor region XR3′ are respectively disposed on both sides of the voltage switch region GR1 in the first horizontal direction HD1.

The first block switch region BR1′, the second block switch region BR2′, the third block switch region BR3′, and the fourth block switch region BR4′ may be regions where the block selection circuit is disposed, and the block selection circuit may be divided into four sections or groups and arranged in the first block switch region BR1′, the second block switch region BR2′, the third block switch regions BR3′, and the fourth block switch region BR4′.

The first block switch region BR1′ and the second block switch region BR2′ may be respectively disposed on both sides of the first pass transistor region XR1′ in the first horizontal direction HD1. The first block switch region BR1′ may be located between the first pass transistor region XR1′ and the first under-cell region UCR1.The second block switch region BR2′ may be located between the first pass transistor region XR1′ and the second under-cell region UCR2.

The first block switch region BR1′ may overlap with the second pass transistor region XR2′ in the second horizontal direction HD2.The second block switch region BR2′ may overlap with the third pass transistor region XR3′ in the second horizontal direction HD2.

The third block switch region BR3′ may be disposed between the second pass transistor region XR2′ and the first page buffer region YR1. The fourth block switch region BR4′ may be disposed between the third pass transistor region XR3′ and the second page buffer region YR2. The third block switch region BR3′ and the fourth block switch region BR4′ may overlap with the second pass transistor region XR2′ and the third pass transistor region XR3′ in the first horizontal direction HD1.The third block switch region BR3′ and the fourth block switch region BR4′ may overlap with the first page buffer region YR1 and the second page buffer region YR2 in the first horizontal direction HD1.

The first peripheral circuit region PR1 may be the remaining region of the first under-cell region UCR1 except for the third block switch region BR3′ and the first page buffer region YR1. The second peripheral circuit region PR2 may be the remaining region of the second under-cell region UCR2 except for the fourth switch circuit region BR4′ and the second page buffer region YR2.

The first peripheral circuit region PR1 may include a first region A1′ that overlaps with the third switch circuit region BR3′ in the second horizontal direction HD2. The second peripheral circuit region PR2 may include a second region A2′ that overlaps with the fourth block switch region BR4′ in the second horizontal direction HD2.

The first peripheral circuit region PR1 and the second peripheral circuit region PR2 may overlap with the first block switch region BR1′ and the second block switch region BR2′ in the first horizontal direction HD1. Because the first block switch region BR1′ and the second block switch region BR2′ are disposed in the under-slim region USR, rather than in the first under-cell region UCR1 or the second under-cell region UCR2, it is possible to increase the area available for arranging peripheral circuits in the first under-cell region UCR1 and the second under-cell region UCR2, which may contribute to reducing the size of the memory device.

FIGS. 3 to 5 illustrate a second semiconductor layer L2 including two cell areas and one slim area, but embodiments of the present disclosure are not limited thereto. The second semiconductor layer may include at least one cell area and at least one slim area.

FIGS. 3 to 5 illustrate a block selection circuit disposed in an under-slim region, but embodiments of the present disclosure are not limited thereto. The entire block selection circuit may be disposed in an under-slim region.

The above description and the accompanying drawings provide examples of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to explain the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure.

What is claimed is:

1. A memory device comprising:
a first semiconductor layer including a slim area, and a first cell area and a second cell area respectively arranged on both sides of the slim area in a first horizontal direction; and
a second semiconductor layer, which vertically overlaps with the first semiconductor layer, and includes a pass transistor circuit connected to the first cell area and the second cell area through a word line, a block selection circuit for providing a block selection signal to the pass transistor circuit, and a voltage switch circuit for transmitting an operating voltage to the pass transistor circuit,
wherein the voltage switch circuit includes a voltage switch region disposed in an under-slim region of the second semiconductor layer,
wherein the under-slim region vertically overlaps with the slim area, and
wherein at least a part of the block selection circuit is disposed in the under-slim region.

2. The memory device of claim 1, wherein the block selection circuit includes a first block switch region, a second block switch region, and a third block switch region,
wherein the first block switch region is disposed in the under-slim region,
wherein the second block switch region is disposed in a first under-cell region of the second semiconductor layer vertically overlapping with the first cell area,
wherein the third block switch region is disposed in a second under-cell region of the second semiconductor layer vertically overlapping with the second cell area.

3. The memory device of claim 2, wherein the pass transistor circuit includes a first pass transistor region and a second pass transistor region disposed in the under-slim region,
wherein the first pass transistor region and the second pass transistor region are spaced apart from each other in the first horizontal direction,
wherein the voltage switch region and the first block switch region are disposed between the first pass transistor region and the second pass transistor region.

4. The memory device of claim 3, wherein the voltage switch region and the first block switch region overlap with each other in a second horizontal direction that is perpendicular to the first horizontal direction.

5. The memory device of claim 2, wherein the second semiconductor layer further includes a peripheral circuit,
wherein the peripheral circuit includes a first peripheral circuit region disposed in the first under-cell region and a second peripheral circuit region disposed in the second under-cell region,
wherein the first peripheral circuit region and the second peripheral circuit region overlap with the first block switch region in the first horizontal direction.

6. The memory device of claim 5, wherein the first peripheral circuit region includes a first region overlapping with the second block switch region in a second horizontal direction,
wherein the second peripheral circuit region includes a second region overlapping with the third block switch region in the second horizontal direction,
wherein the second horizontal direction is perpendicular to the first horizontal direction.

7. The memory device of claim 2, wherein the second semiconductor layer further includes a page buffer circuit,
wherein the page buffer circuit includes a first page buffer region disposed in the first under-cell region and a second page buffer region disposed in the second under-cell region,
wherein the second block switch region and the third block switch region overlap with the first page buffer region and the second page buffer region in the first horizontal direction.

8. The memory device of claim 1, wherein the pass transistor circuit includes a first pass transistor region, a second pass transistor region and a third pass transistor region disposed in the under-slim region,
wherein the first pass transistor region overlaps with the voltage switch region in a second horizontal direction perpendicular to the first horizontal direction,
wherein the second pass transistor region and the third pass transistor region are disposed on both sides of the voltage switch region in the first horizontal direction, respectively.

9. The memory device of claim 8, wherein the block selection circuit includes a first block switch region, a second block switch region, a third block switch region, and a fourth block switch region,
wherein the first block switch region and the second block switch region are respectively disposed on both sides of the first pass transistor region in the first horizontal direction in the under-slim region,
wherein the third block switch region is disposed in a first under-cell region of the second semiconductor layer vertically overlapping with the first cell area,
wherein the fourth block switch region is disposed in a second under-cell region of the second semiconductor layer vertically overlapping with the second cell area.

10. The memory device of claim 9, wherein the second semiconductor layer further includes a peripheral circuit,
wherein the peripheral circuit includes a first peripheral circuit region disposed in the first under-cell region and a second peripheral circuit region disposed in the second under-cell region,
wherein the first peripheral circuit region and the second peripheral circuit region overlap with the first block switch region and the second block switch region in the first horizontal direction.

11. The memory device of claim 10, wherein the first peripheral circuit region includes a first region overlapping with the third block switch region in the second horizontal direction,
wherein the second peripheral circuit region includes a second region overlapping with the fourth block switch region in the second horizontal direction.

12. The memory device of claim 9, wherein the second semiconductor layer further includes a page buffer circuit,
wherein the page buffer circuit includes a first page buffer region disposed in the first under-cell region and a second page buffer region disposed in the second under-cell region,
wherein the third block switch region and the fourth block switch region overlap with the first page buffer region and the second page buffer region in the first horizontal direction.

13. A memory device comprising:
a first semiconductor layer including a cell area and a slim area that are arranged in a first horizontal direction; and
a second semiconductor layer that vertically overlaps with the first semiconductor layer and includes a pass transistor circuit connected to the cell area through a word line, a block selection circuit for providing a block selection signal to the pass transistor circuit, and a voltage switch circuit for transmitting an operating voltage to the pass transistor circuit;
wherein the voltage switch circuit includes a voltage switch region disposed in an under-slim region of the second semiconductor layer,
wherein the under-slim region vertically overlaps with the slim area, and
wherein at least a part of the block selection circuit is disposed in the under-slim region.

14. The memory device of claim 13, wherein the block selection circuit includes a first block switch region and a second block switch region,
wherein the first block switch region is disposed in the under-slim region,
wherein the second block switch region is disposed in an under-cell region of the second semiconductor layer, and the under-cell region vertically overlaps with the cell area.

15. The memory device of claim 14, wherein the voltage switch region overlaps with the first block switch region in a second horizontal direction,
wherein the second horizontal direction is perpendicular to the first horizontal direction.

16. The memory device of claim 15, wherein the pass transistor circuit includes a first pass transistor region and a second pass transistor region disposed in the under-slim region,
wherein the voltage switch region and the first block switch region are disposed between the first pass transistor region and the second pass transistor region.

17. The memory device of claim 14, wherein the second semiconductor layer further includes a peripheral circuit,
wherein the peripheral circuit includes a peripheral circuit region disposed in the under-cell region,
wherein the peripheral circuit region overlaps with the first block switch region in the first horizontal direction.

18. The memory device of claim 17, wherein the peripheral circuit region includes a first region overlapping with the second block switch region in a second horizontal direction,
wherein the second horizontal direction is perpendicular to the first horizontal direction.

19. The memory device of claim 13, wherein the pass transistor circuit includes a first pass transistor region, a second pass transistor region, and a third pass transistor region disposed in the under-slim region,
wherein the voltage switch region overlaps with the first pass transistor region in a second horizontal direction perpendicular to the first horizontal direction,
wherein the second pass transistor region and the third pass transistor region are disposed on both sides of the voltage switch region in the first horizontal direction, respectively.

20. The memory device of claim 19, wherein the block selection circuit includes a first block switch region, a second block switch region, and a third block switch region,
wherein the first block switch region and the second block switch region are respectively disposed on both sides of the first pass transistor region in the first horizontal direction in the under-slim region,
wherein the third block switch region is disposed in an under-cell region of the second semiconductor layer vertically overlapping with the cell area.
